(19) United States
(12) Patent Application Publication
(10) Pub. No.: US 2024/0352275 A1
(43) Pub. Date: Oct. 24, 2024

(54) CURED RESIN FILM, SEMICONDUCTOR DEVICE AND METHOD FOR PRODUCING SEMICONDUCTOR DEVICE

(71) Applicant: Resonac Corporation, Tokyo (JP)

(72) Inventors: Yuki IMAZU, Tokyo (JP); Masaya TOBA, Tokyo (JP); Yu AOKI, Tokyo (JP); Yoshimi HAMANO, Tokyo (JP)

(21) Appl. No.: 18/684,930

(22) PCT Filed: Aug. 24, 2022
(86) PCT No.: PCT/JP2022/031898

§ 371 Date: Feb. 20, 2024

(30) Foreign Application Priority Data
Aug. 25, 2021 (WO) PCT/JP2021/031179

(51) Int. Cl. C09D 163/04; C09D 125/16; C09D 179/08; H01L 21/768

(52) U.S. Cl. CPC C09D 163/04; C09D 125/16; C09D 179/08; H01L 21/76873

(57) ABSTRACT

A semiconductor device production method including: applying a resin composition onto a substrate and drying the resin composition to form a resin film; heating the resin film to obtain a cured resin film; forming a metal seed layer by sputtering on a surface of the cured resin film; forming a resist pattern having an opening portion for forming a wiring pattern on a surface of the metal seed layer; forming a metal layer having a wiring pattern with a wiring width of 3 μm or less and an inter-wiring distance of 3 μm or less by electrolytic plating in a region on the surface of the metal seed layer exposed from the resist pattern; removing the resist pattern; and removing the metal seed layer exposed by the removal of the resist pattern, wherein a cross-linking density of the cured resin film is 0.1×10⁻³ to 110×10⁻³ mol/cm³.

### TECHNICAL FIELD

The present invention relates to a cured resin film, a semiconductor device, and a method for producing a semiconductor device.

### BACKGROUND ART

In order to increase the density and the performance of a semiconductor package, a semiconductor device has been proposed in which semiconductor elements (hereinafter, referred to as “chips” in accordance with a case) with difference performance are mixed in one package, and a high-density interconnect technology between the chips for enabling high-speed transmission and downsizing has been important (for example, refer to Patent Literature 1).

As an additional high-density packaging technology, a package technology (an organic interposer) using an organic substrate having high-density wiring, a fan-out package technology (FO-WLP) having a through mold via (TMV), a package technology using silicon or a glass interposer, a package technology using a through silicon via (TSV), a package technology using a chip embedded in a substrate for inter-chip transmission, and the like have been proposed. In particular, in FO-WLP, it has been proposed to use a fine wiring layer to attain high-density conduction in a case where the chips are mounted in parallel (for example, refer to Patent Literature 2).

### CITATION LIST

### Patent Literature

Patent Literature 1: JP 2012-529770 A

Patent Literature 2: US 2011/0221071 A

### SUMMARY OF INVENTION

### Technical Problem

Recently, the semiconductor element has tended to be downsized, and there has been a demand for a wiring substrate having a fine wiring pattern (in particular, Line/Space (L/S) of 3 μm/3 μm or less). In the formation of fine wiring in the fan-out package technology, it is general to implement a step of forming a metal seed layer by general sputtering on a cured resin film to be a base, a step of forming a resist, a step of performing electroplating, a step of removing the resist, and a step of removing (etching) the metal seed layer. In a case where metals configuring the metal seed layer deeply penetrate inside the cured resin film that is the base, the wirings formed on the cured film are electrically connected, a short-circuit may occur between the wirings, and as an inter-wiring distance decreases, it is difficult to remove the metal seed layer between the wirings.

An object of the present disclosure is to provide a cured resin film usable as a base for forming fine wiring, a semiconductor device including the cured resin film, and a method for producing a semiconductor device.

### Solution to Problem

One aspect of the present disclosure relates to a method for producing a semiconductor device, including: a step of applying a resin composition onto a substrate and drying the resin composition to form a resin film; a step of heating the resin film to obtain a cured resin film; a step of forming a metal seed layer by sputtering on a surface of the cured resin film; a step of forming a resist pattern having an opening portion for forming a wiring pattern on a surface of the metal seed layer; a step of forming a metal layer having a wiring pattern with a wiring width of 3 μm or less and an inter-wiring distance of 3 μm or less by electrolytic plating in a region on the surface of the metal seed layer, which is exposed from the resist pattern; a step of removing the resist pattern; and a step of removing the metal seed layer exposed by the removal of the resist pattern, in this order, in which a cross-linking density of the cured resin film is 0.1×10⁻³ to 110×10⁻³ mol/cm³.

Another aspect of the present disclosure relates to a cured resin film used as a base of a wiring pattern with a wiring width of 3 μm or less and an inter-wiring distance of 3 μm or less, in which a cross-linking density is 0.1×10⁻³ to 110×10⁻³ mol/cm³.

Another aspect of the present disclosure relates to a semiconductor device, including the cured resin film described above as a base of wiring with a wiring width of 3 μm or less and an inter-wiring distance of 3 μm or less.

### Advantageous Effects of Invention

According to the present disclosure, it is possible to provide the cured resin film usable as the base for forming fine wiring, the semiconductor device including the cured resin film, and the method for producing a semiconductor device.

### BRIEF DESCRIPTION OF DRAWINGS

FIG. 1 is a sectional view schematically illustrating a production process of a wiring substrate.

### DESCRIPTION OF EMBODIMENTS

The contents of a cured resin film, a semiconductor device, and a method for producing a semiconductor device according to an embodiment of the present disclosure will be listed below.

[1] A method for producing a semiconductor device, including: a step of applying a resin composition onto a substrate and drying the resin composition to form a resin film; a step of heating the resin film to obtain a cured resin film; a step of forming a metal seed layer by sputtering on a surface of the cured resin film; a step of forming a resist pattern having an opening portion for forming a wiring pattern on a surface of the metal seed layer; a step of forming a metal layer having a wiring pattern with a wiring width of 3 μm or less and an inter-wiring distance of 3 μm or less by electrolytic plating in a region on the surface of the metal seed layer, which is exposed from the resist pattern; a step of removing the resist pattern; and a step of removing the metal seed layer exposed by the removal of the resist pattern, in this order, in which a cross-linking density of the cured resin film is 0.1×10⁻³ to 110×10⁻³ mol/cm³.

[2] The method for producing a semiconductor device according to [1] described above, in which a storage elastic modulus at 140°° C. of the cured resin film is 1.0 GPa or more.

[3] The method for producing a semiconductor device according to [1] or [2] described above, in which a glass transition temperature of the cured resin film is 200°° C. or higher.

[4] The method for producing a semiconductor device according to any one of [1] to [3] described above, in which the cross-linking density of the cured resin film is 60×10⁻³ mol/cm³ or less.

[5] The method for producing a semiconductor device according to any one of [1] to [4] described above, in which the resin composition includes a base polymer (A) and a cross-linking component (B), and the base polymer (A) contains a polymer having a phenolic hydroxyl group, a carboxy group, an imide group, a benzoxazole group, or a photopolymerizable ethylenically unsaturated group.

[6] A cured resin film used as a base of a wiring pattern with a wiring width of 3 μm or less and an inter-wiring distance of 3 μm or less, in which a cross-linking density is 0.1×10⁻³ to 110×10⁻³ mol/cm³.

[7] The cured resin film according to [6] described above, in which a storage elastic modulus at 140° C. is 1.0 GPa or more.

[8] The cured resin film according to [6] or [7] described above, in which a glass transition temperature is 200°° C. or higher.

[9] The cured resin film according to any one of [6] to [8] described above, in which the cross-linking density of the cured resin film is 60×10⁻³ mol/cm³ or less.

The cured resin film according to any one of [6] to [9] described above, in which the cured resin film includes a cured material of a resin composition including a base polymer (A) and a cross-linking component (B), and the base polymer (A) contains a polymer having a phenolic hydroxyl group, a carboxy group, an imide group, a benzoxazole group, or a photopolymerizable ethylenically unsaturated group.

A semiconductor device, including the cured resin film according to any one of [6] to described above as a base of wiring with a wiring width of 3 μm or less and an inter-wiring distance of 3 μm or less.

Hereinafter, an embodiment of the present disclosure will be described in detail with reference to the drawings as necessary. In the following description, the same reference numerals will be applied to the same or corresponding parts, and the repeated description will be omitted. In addition, a positional relationship such as the left, right, top, and bottom is based on a positional relationship illustrated in the drawings, unless otherwise specified. Further, a dimension ratio in the drawings is not limited to the illustrated ratio. Note that, the present invention is not limited to the following embodiment, and can be implemented with various modifications within the scope of the gist.

In a case where terms such as “left”, “right”, “front”, “back”, “up”, “down”, “upper”, and “lower” are used in the claims and the description of this specification, such terms are intended to be illustrative and do not necessarily mean to be in permanent relative positions. In this specification, the term “step” includes not only an independent step but also a step that is not explicitly distinguishable from other steps insofar as a desired function of the step is attained. In addition, the term “layer” includes not only a structure in which a layer is formed on the entire surface but also a structure in which a layer is formed on a part of the surface when observed as a plan view.

In this specification, a numerical range represented by using “to” indicates a range including numerical values described before and after “to” as the minimum value and the maximum value, respectively. In numerical ranges described in stages in this specification, the upper limit value or the lower limit value of a numerical range in a certain stage may be replaced with the upper limit value or the lower limit value of a numerical range in the other stage. In addition, in the numerical range described in this specification, the upper limit value or the lower limit value of the numerical range may be replaced with values described in Examples.

When referring to the amount of each component in a composition in this specification, in a case where there are a plurality of substances corresponding to each component in the composition, unless otherwise specified, the amount of each component in the composition indicates the total amount of the plurality of substances in the composition. In this specification, a “(meth) acrylic acid” indicates at least one of an “acrylic acid” and a “methacrylic acid” corresponding thereto. The same applies to other similar expressions such as (meth)acrylate.

### Method for Producing Semiconductor Device

A method for producing a semiconductor device according to this embodiment includes a step of applying a resin composition onto a substrate and drying the resin composition to form a resin film, a step of heating the resin film to form a cured resin film, a step of forming a metal seed layer by sputtering on the surface of the cured resin film, a step of forming a resist pattern having an opening portion for forming a wiring pattern on the surface of the metal seed layer, a step of forming a metal layer having a wiring pattern with a wiring width of 3 μm or less and an inter-wiring distance of 3 μm or less by electrolytic plating in a region on the surface of the metal seed layer, which is exposed from the resist pattern, a step of removing the resist pattern, and a step of removing the metal seed layer exposed by the removal of the resist pattern, in this order, in which the cross-linking density of the cured resin film is 0.1×10⁻³ to 110×10⁻³ mol/cm³.

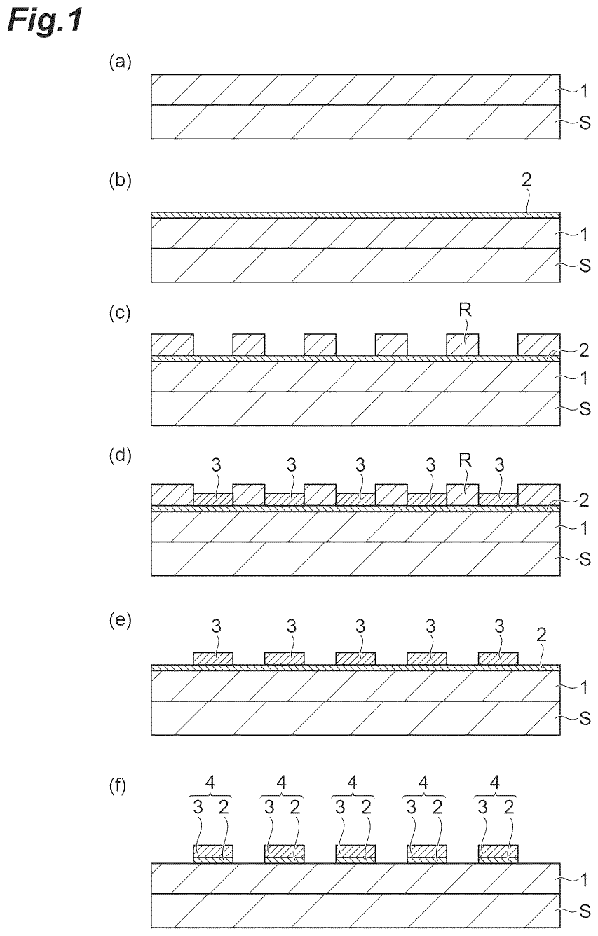

FIG. 1 is a sectional view schematically illustrating a production process of a wiring substrate according to one embodiment of the present disclosure. Hereinafter, each step will be described.

### Applying and Drying Step

First, a resin composition is applied onto a substrate and dried to form a resin film. In this step, the substrate such as a glass substrate, a semiconductor, a metal oxide insulator (for example, TiO₂, SiO₂, and the like), and silicon nitride is spin-coated with the resin composition by using a spinner or the like to form a coated film. The substrate on which such a coated film is formed is dried by using a hot plate, an oven, or the like. Accordingly, the resin film is formed on the substrate. A drying temperature may be 80 to 140° C., 90 to 135° C., or 100 to 130° C., and a drying time may be 1 to 7 minutes, 1 to 6 minutes, or 2 to 5 minutes.

### Heating Treatment Step

In a heating treatment step, by performing a heating treatment on the resin film, it is possible to form a cured resin film. A heating temperature in the heating treatment step may be 170 to 250° C., 180 to 230° C., or 190 to 225° C., from the viewpoint of sufficiently preventing a damage to an electronic device due to heat.

The heating treatment, for example, can be performed by using an oven such as a quartz tube furnace, a hot plate, rapid thermal anneal, a vertical diffusion furnace, an infrared-ray curing furnace, an electron-beam curing furnace, and a microwave curing furnace. In addition, either the atmospheric air or an inert atmosphere such as nitrogen can be selected, and nitrogen is desirable since the oxidation of a pattern can be prevented. Since the range of the heating temperature described above is lower than that of a heating temperature in the related art, it is possible to suppress a damage to the substrate and the electronic device to be small. Therefore, by using the method for producing a cured resin film according to this embodiment, it is possible to produce the electronic device with an excellent yield, which leads to the energy saving of the process.

A heating treatment time in the heating treatment step may be a time sufficient to cure the resin composition, and it is preferable that the heating treatment time is approximately 5 hours or shorter from a balance with a working efficiency. The heating time may be 1.0 to 2.5 hours, 1.5 to 2.5 hours, or 1.8 to 2.2 hours.

The heating treatment can also be performed by using a microwave curing device or a frequency variable microwave curing device in addition to the oven described above. By using such devices, it is possible to effectively heat only the resin film while maintaining the temperature of the substrate or the electronic device at a desired temperature (for example, 200° C. or lower).

In the frequency variable microwave curing device, since the microwave is irradiated into the shape of a pulse while the frequency is changed, it is possible to prevent a standing wave, and homogeneously heat the surface of the substrate. In addition, in the case of including metal wiring as a substrate, as with an electronic component to be described below, when the microwave is irradiated into the shape of a pulse while the frequency is changed, it is possible to prevent the occurrence of discharge from metals, and protect the electronic component from being damaged. Further, when heating is performed by using a frequency variable microwave, even in the case of decreasing a curing temperature, the physical properties of the cured resin film are less likely to be degraded, compared to the case of using an oven (refer to J. Photopolym. Sci. Technol., 18, 327-332 (2005)).

The frequency of the frequency variable microwave is in a range of 0.5 to 20 GHz, and practically, may be in a range of 1 to 10 GHz or a range of 2 to 9 GHz. In addition, it is desirable that the frequency of the microwave to be irradiated is continuously changed, but actually, the microwave is irradiated by changing the frequency in a stepwise manner. In this case, since the standing wave, the discharge from the metals, or the like is less likely to occur when a time for irradiating a single-frequency microwave is minimized, a microwave irradiation time is preferably 1 millisecond or shorter, and more preferably 100 microseconds or shorter.

The output of the microwave to be irradiated is different in accordance with the size of the device or the amount of heated body, and is in a range of approximately 10 to 2000 W, and practically, may be 100 to 1000 W, 100 to 700 W, or 100 to 500 W. In a case where the output is 10 W or more, it is easy to heat the heated body within a short period, and in a case where the output is 2000 W or less, a rapid temperature increase is less likely to occur.

It is preferable to irradiate the microwave by turning on and off the microwave into the shape of a pulse. By irradiating the microwave into the shape of a pulse, it is possible to retain a set heating temperature, and avoid a damage to a cured film and a base material. A time for irradiating a pulse-shaped microwave once is different in accordance with a condition, and it is preferable that the time is approximately 10 seconds or shorter.

According to the steps described above, as illustrated in (a) of FIG. 1, a cured resin film 1 to be an insulating resin layer is formed on a substrate S. The thickness of the cured resin film 1 may be 1 to 20 μm, 3 to 15 μm, or 5 to 10 μm, from the viewpoint of insulating reliability.

### Metal Seed Layer Forming Step

In a metal seed layer forming step, it is possible to form a metal thin film layer to be a metal growth origin of metal wiring formed by electrolytic plating. After heating and drying the cured resin film that is a base at 100°° C. for 30 minutes, a surface treatment is implemented by an argon ion beam to form a metal thin film layer of titanium, and then, form a metal thin film layer of copper by a sputtering method.

It is preferable that the heating and drying is implemented at 85° C. or higher from the viewpoint of removing the moisture, and it is preferable that the heating and drying is implemented at 150° C. or lower from the viewpoint of softening the cured resin film by heating.

Accordingly, as illustrated in (b) of FIG. 1, a metal seed layer 2 composed of a titanium seed layer and a copper seed layer is formed on the surface of the cured resin film 1. The thickness of the metal seed layer 2 is preferably 20 to 200 nm, more preferably 40 to 190 nm, and even more preferably 60 to 180 nm. The thickness of the titanium seed layer, for example, may be 10 to 150 nm, and the thickness of the copper seed layer, for example, may be 50 to 190 nm.

### Resist Pattern Forming Step

By using a photosensitive resin material for forming a resist pattern, a photosensitive resin film is formed on the metal seed layer. In a case where the photosensitive resin material is liquid, the photosensitive resin material is applied onto the metal seed layer by using a spinner or the like to form a coated film. The substrate on which the coated film is formed is dried by using a hot plate, an oven, or the like. In a case where the photosensitive resin material is in the shape of a film, the photosensitive resin film is laminated on the metal seed layer by using a laminator or the like. Accordingly, the photosensitive resin film is formed on the metal seed layer. By implementing an exposing step and a developing step with respect to the formed photosensitive resin film, it is possible to form the resist pattern.

In the exposing step, the photosensitive resin film formed on the substrate is irradiated with an active light ray such as an ultraviolet ray, a visible light ray, and a radioactive ray via a mask. After exposure, as necessary, it is possible to perform heating after exposure (PEB). It is preferable that the temperature of the heating after exposure is 70 to 140° C., and a time for the heating after exposure is 1 minute to 5 minutes.

In the developing step, by removing an exposed portion or an unexposed portion of the photosensitive resin film after the exposing step with a developer, the resin film is patterned, and a patterned resin film is obtained. In a case where the photosensitive resin material is positive, the exposed portion is removed with the developer. In a case where the photosensitive resin material is negative, the unexposed portion is removed with the developer.

As illustrated in (c) of FIG. 1, a resist pattern R is formed on the surface of the metal seed layer 2. The resist pattern R may be provided with an opening portion for forming wiring, and as necessary, other opening portions.

As the developer in the case of performing development using an alkaline aqueous solution, for example, an alkaline aqueous solution such as sodium hydroxide, potassium hydroxide, sodium silicate, ammonia, ethyl amine, diethyl amine, triethyl amine, triethanol amine, and tetramethyl ammonium hydroxide (TMAH) is preferably used. It is preferable that the base concentration of such an aqueous solution is 0.1 to 10% by mass. The developer can also be used by adding alcohols or a surfactant to the developer. Each of the alcohols and the surfactant may be compounded in a range of 0.01 to 10 parts by mass or 0.1 to 5 parts by mass with respect to 100 parts by mass of the developer.

As the developer in the case of performing development using an organic solvent, for example, a good solvent such as cyclopentanone, N,N-dimethyl formamide, dimethyl sulfoxide, N,N-dimethyl acetamide, N-methyl-2-pyrrolidone, γ-butyrolactone, and acetic acid esters, and a mixed solvent of the good solvent and a poor solvent such as lower alcohol, water, and aromatic hydrocarbon are used.

### Electrolytic Copper Plating Step

Next, in an electrolytic plating step, in the opening portion of the obtained resist pattern, copper wiring is formed by electrolytic plating on the exposed metal seed layer. By feeding power to the metal seed layer 2, electrolytic copper plating is implemented, and a wiring portion 3 is formed (refer to (d) of FIG. 1). The thickness of the wiring portion 3 is preferably 1 to 10 μm, more preferably 2 to 10 μm, and even more preferably 3 to 10 μm.

### Resist Pattern Removing Step

After the wiring portion is formed, in a resist pattern removing step, the resist pattern R formed on the metal seed layer 2 is removed by using a resist stripper (refer to (e) of FIG. 1). The resist pattern R can be removed by using a commercially available resist stripper.

As the resist stripper, for example, an amine-based stripper (manufactured by MITSUBISHI GAS CHEMICAL COMPANY, INC., Product Name: R-100), N-methyl-2-pyrrolidone (NMP), an aqueous solution of 2.38% tetramethyl ammonium hydroxide (TMAH), and the like can be used.

### Metal Seed Layer Removing Step

In a metal seed layer removing step, the metal seed layer exposed by the removal of the resist pattern R is removed by using an etchant. Accordingly, as illustrated in (f) of FIG. 1, a metal wiring 4 composed of the metal seed layer 2 remaining on the surface of the cured resin film 1, and the wiring portion 3 is formed. The metal wiring 4 has a wiring width of 3 μm or less and an inter-wiring distance of 3 μm or less.

As the etchant of the copper seed layer, for example, an acidic etchant (manufactured by MITSUBISHI GAS CHEMICAL COMPANY, INC., Product Name: WLC-C2), ammonium persulfate, and the like can be used. As the etchant of the titanium seed layer, for example, a mixed liquid of an acidic etchant (manufactured by MITSUBISHI GAS CHEMICAL COMPANY, INC., Product Name: WTC-T) and an aqueous solution of 28% ammonia can be used.

### Cured Resin Film

The cured resin film according to this embodiment is a cured resin film used as a base of a wiring pattern formed to have a wiring width of 3 μm or less and an inter-wiring distance of 3 μm or less, and has a cross-linking density of 0.1×10⁻³ to 110×10⁻³ mol/cm³.

By setting the cross-linking density of the cured resin film to be in the range described above, it is possible to completely remove the metal seed layer by the etchant while maintaining excellent adhesiveness with the metal seed layer formed by sputtering.

It is general that the metal seed layer is removed by immersing the substrate in the etchant such that the metal seed layer is dissolved, after the metal wiring is formed. In a case where the cross-linking density of the cured resin film is low when forming the metal seed layer by sputtering on the surface of the cured resin film, metals easily penetrate inside the cured resin film. An etching time required for removing the metals that have deeply penetrated inside the cured resin film increases, the metal wiring may be excessively dissolved, and the shape defect of the wiring occurs. In a case where the metals remain inside the cured resin film without being completely removed by the etchant, a current flowing the metal wiring formed on the cured resin film may cause a short-circuit between the wirings. As the inter-wiring distance decreases, the etchant is less likely to penetrate between the wirings, and it is difficult to remove the metal seed layer between the wirings. By setting the cross-linking density of the cured resin film to 0.1×10⁻³ mol/cm³ or more, it is possible to reduce the depth that the metal penetrates.

On the other hand, in a case where the metals do not penetrate inside the cured resin film at all, an anchor effect is not exhibited, and adhesiveness between the metal seed layer and the cured resin film decreases. By setting the cross-linking density of the cured resin film to 110×10⁻³ mol/cm³ or less, it is possible to adjust the depth that the metals penetrate inside the cured resin film such that the anchor effect is exhibited.

The cross-linking density of the cured resin film may be 0.5×10⁻³ mol/cm³ or more, 1.0×10⁻³ mol/cm³ or more, 5.0×10⁻³ mol/cm³ or more, or 10×10⁻³ mol/cm³ or more, from the viewpoint of the adhesiveness with the metal seed layer. The upper limit value of the cross-linking density of the cured resin film may be 105×10⁻³ mol/cm³ or less, 100×10⁻³ mol/cm³ or less, or 90×10⁻³ mol/cm³ or less, from the viewpoint of the removability of the metal seed layer.

It is generally known that there is a correlation between the cross-linking density of the cured resin film and the remaining stress in the cured resin film. When forming the cured resin film on the substrate, it is possible to reduce the warpage of the entire substrate including the cured resin film as the remaining stress decreases. Therefore, it is assumed that by reducing the cross-linking density of the cured resin film, it is possible to expect a reduction in the warpage of the entire substrate including the cured resin film. From the viewpoint of reducing the warpage, the cross-linking density of the cured resin film is preferably 80×10⁻³ mol/cm³ or less, more preferably 70×10⁻³ mol/cm³ or less, and even more preferably 60×10⁻³ mol/cm³ or less.

The cross-linking density can be calculated by the following expression from a storage elastic modulus at 300° C. (573K) to be measured in a viscoelastic test. In the expression, E′ indicates the storage elastic modulus at 573K, R indicates a gas constant, and T indicates 573K.

Cross-Linking Density=E′/3RT

The storage elastic modulus can be measured by the following procedure. The cured film is cut out into the shape of a strip having a width of 10 mm and a length of 100 mm to prepare a strip sample of the cured resin film. By using a dynamic viscoelasticity measurement device, the viscoelastic test of the strip sample is performed by increasing the temperature from 40 to 350° C. at an interchuck distance of 20 mm, a frequency of 10 Hz, and a temperature increase rate of 5° C./minute, and the storage elastic modulus at 140° C. is measured.

The storage elastic modulus at 140° C. of the cured resin film according to this embodiment is preferably 1.0 GPa or more, more preferably 1.1 GPa or more, even more preferably 1.3 GPa or more, and still even more preferably 2.0 GPa or more, from the viewpoint of reducing the depth that the metal seed layer penetrates inside the cured resin film by sputtering. The storage elastic modulus at 140° C. of the cured resin film may be 4.0 GPa or less, 3.8 GPa or less, or 3.4 GPa or less.

The glass transition temperature (Tg) of the cured resin film according to this embodiment is preferably 200° C. or higher from the viewpoint of reducing the thermal deformation of the cured resin film in a sputtering pretreatment, and may be 210° C. or higher, 220° C. or higher, or 230° C. or higher. Tg of the cured resin film may be 200 to 300° C., 210 to 280° C., 220 to 270°° C., or 230 to 265° C. Tg is a temperature indicating the maximum value of tan δ.

The cured resin film according to this embodiment can be formed by using a resin composition including a base polymer (A) and a cross-linking component (B). The cured resin film according to this embodiment contains a cured material of the resin composition including the base polymer (A) and the cross-linking component (B). Hereinafter, each component that can be contained in the resin composition will be described in detail.

### Component (A): Base Polymer

As the component (A), a polymer having a phenolic hydroxyl group, a carboxy group, an imide group, a benzoxazole group, or a photopolymerizable ethylenically unsaturated group can be used.

The polymer having a phenolic hydroxyl group may be an alkali-soluble resin. Examples of the polymer having a phenolic hydroxyl group include a polyimide resin, a polybenzoxazole resin, a polyamide resin, a phenol/formaldehyde-condensed novolak resin, a cresol/formaldehyde-condensed novolak resin, a phenol-naphthol/formaldehyde-condensed novolak resin, polyhydroxystyrene or a copolymer thereof, a phenol-xylene glycol condensation resin, a cresol-xylene glycol condensation resin, a phenol-dicyclopentadiene condensation resin, and an acrylic polymer having a phenolic hydroxyl group.

As the acrylic polymer having a phenolic hydroxyl group, for example, an acrylic polymer having a structural unit represented by Formula (1) described below can be used. In Formula (1), R₁ represents a hydrogen atom or a methyl group.

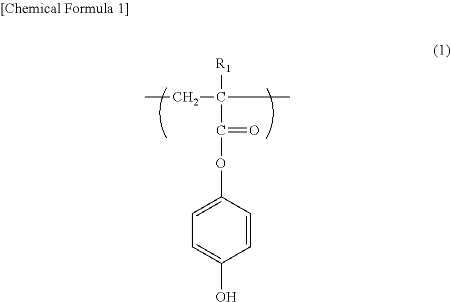

The phenolic hydroxyl equivalent of the acrylic polymer having a phenolic hydroxyl group may be 200 to 700 g/eq from the viewpoint of pattern forming properties and a reduction in voids during thermal compression bonding.

The acrylic polymer having a phenolic hydroxyl group may be a copolymer having a structural unit represented by Formula (1) as well as a structural unit other than the structural unit represented by Formula (1) (hereinafter, simply referred to as the “other structural unit”), and the other structural unit is a structural unit derived from a monomer copolymerizable with a monomer having the structural unit represented by Formula (1). The monomer having the other structural unit is not particularly limited, and a (meth)acrylate compound or a vinyl compound can be used.

Examples of the monomer having the other structural unit include methyl (meth)acrylate, ethyl (meth)acrylate, propyl (meth)acrylate, butyl (meth)acrylate, octyl (meth)acrylate, methoxymethyl (meth)acrylate, methoxyethyl (meth)acrylate, ethoxyethyl (meth)acrylate, butoxyethyl (meth)acrylate, methoxyethoxyethyl (meth)acrylate, a (meth)acrylic acid, hydroxyethyl (meth)acrylate, (meth)acrylonitrile, dihydrodicyclopentenyl (meth)acrylate, dihydrodicyclopentenyl itaconate, dihydrodicyclopentenyl maleate, dihydrodicyclopentenyl fumarate, dihydrodicyclopentenyl oxyethyl (meth)acrylate, dihydrodicyclopentenyl oxyethyl itaconate, dihydrodicyclopentenyl oxyethyl maleate, dihydrodicyclopentenyl oxyethyl fumarate, divinyl itaconate, divinyl maleate, divinyl fumarate, dicyclopentadiene, methyl dicyclopentadiene, ethylidene norbornene, vinyl (meth)acrylate, 1,1-dimethyl propenyl (meth)acrylate, 3,3-dimethyl butenyl (meth)acrylate, vinyl 1,1-dimethyl propenyl ether, vinyl 3,3-dimethyl butenyl ether, 1-(meth) acryloyloxy-1-phenyl ethene, and 1-(meth)acryloyloxy-2-phenyl ethene.

The polymer having a carboxy group may be an alkali-soluble resin. The polymer having a carboxy group is not particularly limited, and an acrylic polymer having a carboxy group on a side chain is preferably used.

As the component (A), an alkali-soluble resin (A1) having a glass transition temperature (Tg) of 150° C. or higher and an alkali-soluble resin (A2) having Tg of 120° C. or lower may be used by being mixed. According to such a configuration, the cured resin film with more excellent reliability is obtained.

In a case where the alkali-soluble resin (A1) having Tg of 150° C. or higher and the alkali-soluble resin (A2) having Tg of 120° C. or lower are mixed, it is preferable that 5 to 30 parts by mass of the alkali-soluble resin (A2) is compounded with respect to 100 parts by mass of the alkali-soluble resin (A1). In a case where the compounded amount of (A2) is 5 parts by mass or more, there is a tendency that the elongation of the cured resin film is less likely to be degraded and HAST resistance is improved, and in a case where the compounded amount of (A2) is 30 parts by mass or less, there is a tendency that the strength of the cured resin film is less likely to be degraded and the HAST resistance is improved.

As the component (A), an alkali-soluble resin having an imide group may be included from the viewpoint of improving the mechanical characteristics of the cured resin film. As the alkali-soluble resin having an imide group, an acrylic polymer obtained by polymerizing a (meth)acrylate compound having an imide group is preferably used from the viewpoint of arbitrarily adjusting the concentration of the imide group. As the alkali-soluble resin having an imide group, alkali-soluble polyimide can also be used. From the viewpoint of resolution, it is preferable that the alkali-soluble resin having an imide group is used together with a novolak resin or a phenolic resin.

The alkali-soluble resin having an imide group may be a copolymer of a (meth)acrylate compound having an imide group and a (meth)acrylate compound having a phenolic hydroxyl group or a carboxy group.

Examples of the polymer having a photopolymerizable ethylenically unsaturated group include a polyimide precursor such as a polyamide acid ester in which all or a part of carboxy groups in a polyamide acid are esterified. It is preferable that the polyamide acid ester has a photopolymerizable ethylenically unsaturated group. The polyamide acid ester may be a reactant of diamine, a tetracarboxylic dianhydride, and a compound having a photopolymerizable ethylenically unsaturated group.

Examples of the diamine include polyoxypropylene diamine and 2,2′-dimethyl biphenyl-4,4′-diamine (DMAP). Examples of the tetracarboxylic dianhydride include a 4,4′-diphenyl ether tetracarboxylic dianhydride (ODPA). Examples of the compound having a photopolymerizable ethylenically unsaturated group include 2-hydroxyethyl (meth)acrylate (HEMA).

The component (A) may be polyimide having a hydroxyl group. The polyimide having a hydroxyl group may be a reactant of a bisaminophenol compound, diamine, and a tetracarboxylic dianhydride. As the polyimide having a hydroxyl group, for example, a polymer having a structural unit represented by Formula (10) described below can be used.

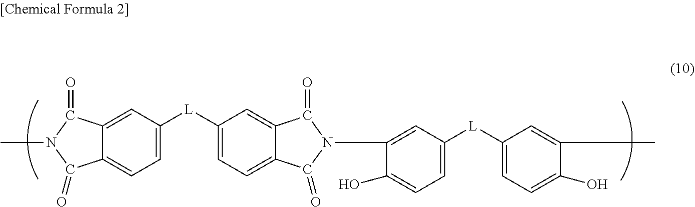

In Formula (10), L may be an ether bond of a group represented by —COO(CH₂)nOCO— (n: 1 to 10), and Y is at least one type of group selected from the group consisting of a hexafluoroisopropylidene group, a sulfonyl group, a carbonyl group, an isopropylidene group, an oxymethylene group, and a methylene group.

It is preferable that the component (A) contains at least one type selected from the group consisting of a polyimide resin, a polyimide precursor, a polybenzoxazole resin, a polybenzoxazole precursor, and an acrylic polymer having a phenolic hydroxyl group. It is preferable that the cured resin film according to this embodiment has an imide skeleton, a benzoxazole skeleton, or a phenol skeleton, from the viewpoint of using a finer wiring pattern as a base.

Tg of the component (A) is the peak temperature of tan δ when the component (A) formed into a film is measured by a viscoelasticity analyzer (manufactured by Rheometric Scientific, Inc., Product Name: RSA-2) in the condition of a temperature increase rate of 5° C./minute, a frequency of 1 Hz, and a measurement temperature of −50 to 300° C.

The lower limit value of the weight average molecular weight (Mw) of the component (A) may be 2500 or more, 3000 or more, 3500 or more, 4000 or more, 8000 or more, 10000 or more, or 15000 or more. The upper limit value of Mw of the component (A) may be 100000 or less, 80000 or less, 60000 or less, 50000 or less, 45000 or less, or 40000 or less. Mw of the component (A), for example, may be 2500 to 100000, 3000 to 80000, 3500 to 60000, or 4000 to 50000.

Mw of the alkali-soluble resin (A1) is preferably 3000 to 50000, may be 3500 to 30000 from the viewpoint of the reliability, or may be 4000 to 25000 from the viewpoint of the resolution when forming the pattern. Mw of the alkali-soluble resin (A2) is preferably 10000 to 80000, may be 15000 to 60000 from the viewpoint of the reliability, or may be 15000 to 40000 from the viewpoint of the resolution when forming the pattern.

In this specification, Mw is a value obtained by being measured with a gel permeation chromatography (GPC) method and converted with a standard polystyrene calibration curve. As a measurement device, for example, high-performance liquid chromatography (manufactured by SHIMADZU CORPORATION, Product Name: C-R4A) can be used.

### Component (B): Cross-Linking Component

The cross-linking component that is the component (B) is a polyfunctional compound having two or more groups having reactivity with respect to heat or light. As the component (B), a thermosetting compound or a photopolymerizable compound can be used. Only one type of component (B) may be used alone, or two or more types thereof may be used in combination.

Examples of the thermosetting compound include an acrylate resin, an epoxy resin, a cyanate ester resin, a maleimide resin, an allyl nadi imide resin, a phenolic resin, a urea resin, a melamine resin, an alkyd resin, an unsaturated polyester resin, a diallyl phthalate resin, a silicone resin, a resorcinol formaldehyde resin, a triallyl cyanurate resin, a polyisocyanate resin, a resin containing tris(2-hydroxyethyl) isocyanurate, a resin containing triallyl trimellitate, and a thermosetting resin synthesized from cyclopentadiene. From the viewpoint of the insulating reliability of the resin composition and the adhesiveness with the metal, it is more preferable that the thermosetting resin is a compound having any one selected from a methylol group, an alkoxyalkyl group, and a glycidyl group.

By compounding a compound having a glycidyl group as the component (B) with the resin composition, the compound reacts with the component (A) to form a cross-linking structure when heating and curing the resin film after the pattern is formed. Accordingly, it is possible to prevent the brittleness and the melting of the cured film. As the compound having a glycidyl group, a known compound of the related art can be used. As the compound having a glycidyl group, for example, a bisphenol A epoxy resin, a bisphenol F epoxy resin, a phenol novolak epoxy resin, a cresol novolak epoxy resin, an alicyclic epoxy resin, glycidyl amine, a heterocyclic epoxy resin, and polyalkylene glycol diglycidyl ether.

As the photopolymerizable compound, a compound having a photopolymerizable ethylenically unsaturated group can be used. Examples of the photopolymerizable compound include α,β-unsaturated carboxylic acid ester of polyhydric alcohol, bisphenol-type (meth)acrylate, an α,β-unsaturated carboxylic acid adduct of a glycidyl group-containing compound, (meth)acrylate having a urethane bond, nonyl phenoxypolyethylene oxyacrylate, (meth)acrylate having a phthalic acid skeleton, and (meth) acrylic acid alkyl ester.

Examples of the α,β-unsaturated carboxylic acid ester of the polyhydric alcohol include polyethylene glycol di(meth)acrylate having 2 to 14 ethylene groups, polypropylene glycol di(meth)acrylate having 2 to 14 propylene groups, polyethylene/polypropylene glycol di(meth)acrylate having 2 to 14 ethylene groups and 2 to 14 propylene groups, trimethylol propane di(meth)acrylate, trimethylol propane tri(meth)acrylate, EO-modified trimethylol propane tri(meth)acrylate, PO-modified trimethylol propane tri(meth)acrylate, EO,PO-modified trimethylol propane tri(meth)acrylate, tetramethylol methane tri(meth)acrylate, tetramethylol methane tetra(meth)acrylate, and a (meth)acrylate compound having a skeleton derived from dipentaerythritol or pentaerythritol. “EO-modified” indicates having a block structure of an ethylene oxide (EO) group, and “PO-modified” indicates having a block structure of a propylene oxide (PO) group.

The content of the component (B) in the resin composition may be 1 to 30 parts by mass, 2 to 28 parts by mass, or 3 to 25 parts by mass, with respect to 100 parts by mass of the component (A), from the viewpoint of solubility to the alkaline aqueous solution and the physical properties of the cured film. The content of the component (B) may be 5 parts by mass or more, 10 parts by mass or more, 15 parts by mass or more, or 20 parts by mass or more, with respect to 100 parts by mass of the component (A), from the viewpoint of increasing the cross-linking density of the cured film.

### Component (C): Photosensitizing Agent

The resin composition may include a photosensitizing agent as a component (C). The resin composition including the component (c) can be used as a photosensitive resin composition for forming a via or a wiring pattern by exposure and development. As the photosensitizing agent, a photoradical polymerization initiator for generating radicals by light irradiation or a photo-acid-generating agent for generating acids by light irradiation can be used.

Examples of the photoradical polymerization initiator include an alkyl phenone-based photopolymerization initiator, an acyl phosphine-based photopolymerization initiator, an intramolecular hydrogen abstraction-type photopolymerization initiator, and a cationic photopolymerization initiator. Examples of commercially available products of such photopolymerization initiators include Omnirad 651, Omnirad 184, Omnirad 1173, Omnirad 2959, Omnirad 127, Omnirad 907, Omnirad 369, Omnirad 379EG, Omnirad 819, Omnirad MBF, Omnirad TPO, and Omnirad 784, which are manufactured by IGM Resins B.V.; and Irgacure OXE01, Irgacure OXE02, Irgacure OXE03, and Irgacure OXE04, which are manufactured by BASF. Only one type of photoradical polymerization initiator may be used alone, or two or more types thereof may be used together, in accordance with the purpose, the usage, or the like.

The photo-acid-generating agent has a function of generating acids by light irradiation and increasing the solubility to the alkaline aqueous solution in a portion irradiated with light. Examples of the photo-acid-generating agent include an o-quinone diazide compound, an aryl diazonium salt, a diaryl iodonium salt, and a triaryl sulfonium salt. Only one type of photo-acid-generating agent may be used alone, or two or more types thereof may be used together, in accordance with the purpose, the usage, or the like.

From the viewpoint of high sensitivity, it is preferable to use the o-quinone diazide compound as the photo-acid-generating agent. As the o-quinone diazide compound, for example, a compound obtained by a condensation reaction between o-quinone diazide sulfonyl chloride and a hydroxy compound, an amino compound, and the like, in the presence of a dehydrochlorination agent. A reaction temperature may be 0 to 40° C., and a reaction time may be 1 to 10 hours.

Examples of the o-quinone diazide sulfonyl chloride include benzoquinone-1,2-diazide-4-sulfonyl chloride, naphthoquinone-1,2-diazide-5-sulfonyl chloride, and naphthoquinone-1,2-diazide-6-sulfonyl chloride.

Examples of the hydroxy compound include hydroquinone, resorcinol, pyrogallol, bisphenol A, bis(4-hydroxyphenyl) methane, 1,1-bis(4-hydroxyphenyl)-1-[4-{1-(4-hydroxyphenyl)-1-methyl ethyl} phenyl] ethane, 2,2-bis(4-hydroxyphenyl) hexafluoropropane, 2,3,4-trihydroxybenzophenone, 2,3,4,4′-tetrahydroxybenzophenone, 2,2′,4,4′-tetrahydroxybenzophenone, 2,3,4,2′,3′-pentahydroxybenzophenone, 2,3,4,3′,4′,5′-hexahydroxybenzophenone, bis(2,3,4-trihydroxyphenyl) methane, bis(2,3,4-trihydroxyphenyl) propane, 4b,5,9b,10-tetrahydro-1,3,6,8-tetrahydroxy-5,10-dimethyl indeno [2,1-a] indene, tris(4-hydroxyphenyl) methane, and tris(4-hydroxyphenyl) ethane.

Examples of the amino compound include p-phenylene diamine, m-phenylene diamine, 4,4′-diaminodiphenyl ether, 4,4′-diaminodiphenyl methane, 4,4′-diaminodiphenyl sulfone, 4,4′-diaminodiphenyl sulfide, o-aminophenol, m-aminophenol, p-aminophenol, 3,3′-diamino-4,4′-dihydroxybiphenyl, 4,4′-diamino-3,3′-dihydroxybiphenyl, bis(3-amino-4-hydroxyphenyl) propane, bis(4-amino-3-hydroxyphenyl) propane, bis(3-amino-4-hydroxyphenyl) sulfone, bis(4-amino-3-hydroxyphenyl) sulfone, bis(3-amino-4-hydroxyphenyl) hexafluoropropane, and bis(4-amino-3-hydroxyphenyl) hexafluoropropane.

From the viewpoint of reactivity when synthesizing the o-quinone diazide compound and from the viewpoint of an appropriate absorption wavelength range when exposing the resin film, it is preferable to use a reaction product of a condensation reaction between 1,1-bis(4-hydroxyphenyl)-1-[4-{1-(4-hydroxyphenyl)-1-methyl ethyl} phenyl] ethane and 1-naphthoquinone-2-diazide-5-sulfonyl chloride, and a reaction product of a condensation reaction between tris(4-hydroxyphenyl) methane or tris(4-hydroxyphenyl) ethane and 1-naphthoquinone-2-diazide-5-sulfonyl chloride.

Examples of the dehydrochlorination agent include sodium carbonate, sodium hydroxide, sodium hydrogen carbonate, potassium carbonate, potassium hydroxide, trimethyl amine, triethyl amine, and pyridine. As a reaction solvent, for example, dioxane, acetone, methyl ethyl ketone, tetrahydrofuran, diethyl ether, and N-methyl-2-pyrrolidone are used.

It is preferable that the o-quinone diazide sulfonyl chloride and the hydroxy compound and/or the amino compound are compounded such that the total number of moles of a hydroxy group and an amino group is 0.5 to 1 mol with respect to 1 mole of the o-quinone diazide sulfonyl chloride. A preferred compounding ratio of the dehydrochlorination agent and the o-quinone diazide sulfonyl chloride is in a range of 0.95/1 to 1/0.95 molar equivalent.

The content of the component (C) may be 1 to 30 parts by mass, 2 to 25 parts by mass, or 3 to 20 parts by mass, with respect to 100 parts by mass of the component (A), from the viewpoint of increasing a difference in a dissolution rate between the exposed portion and the unexposed portion and more excellent sensitivity.

### Low-Molecular Compound Having Phenolic Hydroxyl Group

The resin composition may include a low-molecular compound having a phenolic hydroxyl group. The low-molecular compound having a phenolic hydroxyl group is used to increase the dissolution rate of the exposed portion when developed with the alkaline aqueous solution and improve the sensitivity. By containing the low-molecular compound having a phenolic hydroxyl group, the low-molecular compound having a phenolic hydroxyl group reacts with the component (A) to form a cross-linking structure when heating and curing the resin film after the pattern is formed.

The molecular weight of the low-molecular compound having a phenolic hydroxyl group is preferably 2000 or less, and in consideration of the solubility to the alkaline aqueous solution and a balance between sensitivity characteristics and the physical properties of the cured film, the number average molecular weight (Mn) thereof is preferably 94 to 2000, more preferably 108 to 2000, and even more preferably 108 to 1500.

As the low-molecular compound having a phenolic hydroxyl group, a known compound of the related art can be used, and a compound represented by Formula (2) described below is particularly preferable since the compound is excellent in a balance between an effect of accelerating the dissolution of the exposed portion and an effect of preventing the melting of the resin film when cured.

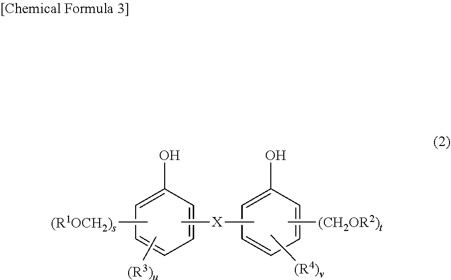

In Formula (2), X represents a single bond or a divalent organic group, R¹, R², R³, and R⁴ each independently represent a hydrogen atom or a monovalent organic group, s and t each independently represent an integer of 1 to 3, and u and v each independently represent an integer of 0 to 4.

In Formula (2), a compound in which X is a single bond is a biphenol (dihydroxybiphenyl) derivative. Examples of the divalent organic group represented by X include an alkylene group having 1 to 10 carbon atoms such as a methylene group, an ethylene group, and a propylene group, an alkylidene group having 2 to 10 carbon atoms such as an ethylidene group, an arylene group having 6 to 30 carbon atoms such as a phenylene group, a group in which a part or all of hydrogen atoms of such hydrocarbon groups are substituted with a halogen atom such as a fluorine atom, a sulfonyl group, a carbonyl group, an ether bond, a thioether bond, and an amide bond. Among them, a divalent organic group represented by Formula (3) described below is preferable.

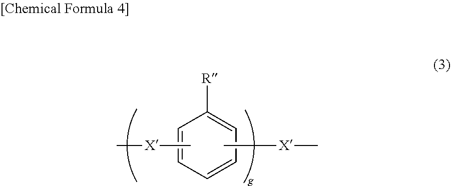

In Formula (3), X′ represents a single bond, an alkylene group (for example, an alkylene group having 1 to 10 carbon atoms), an alkylidene group (for example, an alkylidene group having 2 to 10 carbon atoms), a group in which a part or all of hydrogen atoms thereof are substituted with a halogen atom, a sulfonyl group, a carbonyl group, an ether bond, a thioether bond, or an amide bond, R″ represents a hydrogen atom, a hydroxy group, an alkyl group, or a haloalkyl group, g represents an integer of 1 to 10, and a plurality of R″s may be the same or different from each other.

The compounded amount of the low-molecular compound having a phenolic hydroxyl group may be 1 to 50 parts by mass, 2 to 30 parts by mass, or 3 to 25 parts by mass, with respect to 100 parts by mass of the component (A), from the viewpoint of a development time, an allowable range of the residual film rate of the unexposed portion, and the properties of the cured film.

### Compound for Generating Acids by Heating

The resin composition may include a compound for generating acids by heating. By using the compound for generating acids by heating, acids can be generated when heating the resin film, a reaction between the component (A), the compound having a glycidyl group, and the low-molecular compound having a phenolic hydroxyl group, that is, a thermal cross-linking reaction is accelerated, and the heat resistance of the patterned cured film is improved. In addition, since the compound for generating acids by heating generates acids even by light irradiation, the solubility to the alkaline aqueous solution in the exposed portion increases. Accordingly, a difference in the solubility to the alkaline aqueous solution between the unexposed portion and the exposed portion further increases, and the resolution is further improved.

It is preferable that the compound for generating acids by heating, for example, is a compound for generating acids by heating to 50 to 250° C. Examples of the compound for generating acids by heating include a salt formed of a strong acid and a base, such as an onium salt, and imide sulfonate.

Examples of the onium salt include a diaryl iodonium salt such as an aryl diazonium salt and a diphenyl iodonium salt; a di(alkyl aryl) iodonium salt such as a diaryl iodonium salt and a di(t-butyl phenyl) iodonium salt; a trialkyl sulfonium salt such as a trimethyl sulfonium salt; a dialkyl monoaryl sulfonium salt such as a dimethyl phenyl sulfonium salt; a diaryl monoalkyl iodonium salt such as a diphenyl methyl sulfonium salt; and a triaryl sulfonium salt. Among them, a di(t-butyl phenyl) iodonium salt of a paratoluene sulfonic acid, a di(t-butyl phenyl) iodonium salt of a trifluoromethane sulfonic acid, a trimethyl sulfonium salt of a trifluoromethane sulfonic acid, a dimethyl phenyl sulfonium salt of a trifluoromethane sulfonic acid, a diphenyl methyl sulfonium salt of a trifluoromethane sulfonic acid, a di(t-butyl phenyl) iodonium salt of a nonafluorobutane sulfonic acid, a diphenyl iodonium salt of a camphorsulfonic acid, a diphenyl iodonium salt of an ethane sulfonic acid, a dimethyl phenyl sulfonium salt of a benzene sulfonic acid, and a diphenyl methyl sulfonium salt of a toluene sulfonic acid are preferable.

As the salt formed of the strong acid and the base, a salt formed of the following strong acid and base, in addition to the onium salt described above, for example, a pyridinium salt can also be used. Examples of the strong acid include an aryl sulfonic acid such as a p-toluene sulfonic acid and a benzene sulfonic acid; a perfluoroalkyl sulfonic acid such as a camphorsulfonic acid, a trifluoromethane sulfonic acid, and a nonafluorobutane sulfonic acid; and an alkyl sulfonic acid such as a methane sulfonic acid, an ethane sulfonic acid, and a butane sulfonic acid. Examples of the base include alkyl pyridine such as pyridine and 2,4,6-trimethyl pyridine, N-alkyl pyridine such as 2-chloro-N-methyl pyridine, and halogenated-N-alkyl pyridine.

As the imide sulfonate, for example, naphthoyl imide sulfonate and phthalimide sulfonate can be used.

As the compound for generating acids by heating, in addition to the above, a compound having a structure represented by Formula (4) described below or a compound having a sulfone amide structure represented by Formula (5) described below can also be used.

R⁵R⁶C═N—O—SO₂—R⁷ (4)

—NH—SO₂—R⁸ (5)

In Formula (4), R⁵, for example, is a cyano group, R⁶, for example, is a methoxyphenyl group, a phenyl group, or the like, and R⁷, for example, is an aryl group such as a p-methyl phenyl group and a phenyl group, an alkyl group such as a methyl group, an ethyl group, and an isopropyl group, and a perfluoroalkyl group such as a trifluoromethyl group and a nonafluorobutyl group.

In Formula (5), R⁸, for example, is an alkyl group such as a methyl group, an ethyl group, a propyl group, an aryl group such as a methyl phenyl group and a phenyl group, and a perfluoroalkyl group such as a trifluoromethyl group and nonafluorobutyl. Examples of a group bonded to an N atom of the sulfone amide structure represented by Formula (5) include 2,2′-bis(4-hydroxyphenyl) hexafluoropropane, 2,2′-bis (4-hydroxyphenyl) propane, and di(4-hydroxyphenyl) ether.

The compounded amount of the compound for generating acids by heating may be 0.1 to 30 parts by mass, 0.2 to 20 parts by mass, or 0.5 to 10 parts by mass, with respect to 100 parts by mass of the component (A).

### Elastomer

The resin composition may include an elastomer component.

The elastomer is used to impart flexibility to the cured film of the resin composition. As the elastomer, a known elastomer of the related art can be used, and it is preferable that Tg of a polymer configuring the elastomer is 20° C. or lower.

Examples of the elastomer include a styrene-based elastomer, an olefin-based elastomer, a urethane-based elastomer, a polyester-based elastomer, a polyamide-based elastomer, an acrylic elastomer, and a silicone-based elastomer. Only one type of elastomer can be used alone, or two or more types thereof can be used in combination.

The compounded amount of the elastomer may be 1 to 50 parts by mass or 5 to 30 parts by mass with respect to 100 parts by mass of the component (A). In a case where the compounded amount of the elastomer is 1 part by mass or more, there is a tendency that the thermal shock resistance of the cured film is improved, and in a case where the compounded amount is 50 parts by mass or less, there is a tendency that the resolution and the heat resistance of the cured film to be obtained are less likely to decrease, and compatibility and dispersibility with respect to other components are less likely to decrease.

### Dissolution Accelerator

The resin composition may include a dissolution accelerator. By compounding the dissolution accelerator with the resin composition, it is possible to increase the dissolution rate of the exposed portion when developed with the alkaline aqueous solution, and improve the sensitivity and the resolution. As the dissolution accelerator, a known dissolution accelerator of the related art can be used. Examples of the dissolution accelerator include a compound having a carboxy group, a sulfo group, or a sulfone amide group. The compounded amount in the case of using the dissolution accelerator can be determined by the dissolution rate with respect to the alkaline aqueous solution, and for example, can be 0.01 to 30 parts by mass with respect to 100 parts by mass of the component (A).

### Dissolution Inhibitor

The resin composition may include a dissolution inhibitor. The dissolution inhibitor is a compound for inhibiting the solubility of the component (A) with respect to the alkaline aqueous solution, and used to control the remaining film thickness, the development time, and the contrast. Examples of the dissolution inhibitor include diphenyl iodonium nitrate, bis(p-tert-butyl phenyl) iodonium nitrate, diphenyl iodonium bromide, diphenyl iodonium chloride, and diphenyl iodonium iodide. The compounded amount in the case of using the dissolution inhibitor may be 0.01 to 20 parts by mass, 0.01 to 15 parts by mass, or 0.05 to 10 parts by mass, with respect to 100 parts by mass of the component (A), from the viewpoint of an allowable range of the sensitivity and the development time.

### Coupling Agent

The resin composition may further include a coupling agent. By compounding the coupling agent with the resin composition, it is possible to increase the bonding-adhesiveness of the patterned cured film to be formed with the substrate. Examples of the coupling agent include an organic silane compound and an aluminum chelate compound.

Examples of the organic silane compound include vinyl triethoxysilane, γ-glycidoxypropyl triethoxysilane, γ-methacryloxypropyl trimethoxysilane, urea propyl triethoxysilane, methyl phenyl silane diol, ethyl phenyl silane diol, n-propyl phenyl silane diol, isopropyl phenyl silane diol, n-butyl phenyl silane diol, isobutyl phenyl silane diol, tert-butyl phenyl silane diol, diphenyl silane diol, ethyl methyl phenyl silanol, n-propyl methyl phenyl silanol, isopropyl methyl phenyl silanol, n-butyl methyl phenyl silanol, isobutyl methyl phenyl silanol, tert-butyl methyl phenyl silanol, ethyl n-propyl phenyl silanol, ethyl isopropyl phenyl silanol, n-butyl ethyl phenyl silanol, isobutyl ethyl phenyl silanol, tert-butyl ethyl phenyl silanol, methyl diphenyl silanol, ethyl diphenyl silanol, n-propyl diphenyl silanol, isopropyl diphenyl silanol, n-butyl diphenyl silanol, isobutyl diphenyl silanol, tert-butyl diphenyl silanol, phenyl silane triol, 1,4-bis(trihydroxysilyl) benzene, 1,4-bis(methyl dihydroxysilyl) benzene, 1,4-bis(ethyl dihydroxysilyl) benzene, 1,4-bis(propyl dihydroxysilyl) benzene, 1,4-bis(butyl dihydroxysilyl) benzene, 1,4-bis(dimethyl hydroxysilyl) benzene, 1,4-bis(diethyl hydroxysilyl) benzene, 1,4-bis(dipropyl hydroxysilyl) benzene, and 1,4-bis(dibutyl hydroxysilyl) benzene.

The compounded amount in the case of using the coupling agent is preferably 0.1 to 20 parts by mass, and more preferably 0.5 to 10 parts by mass, with respect to 100 parts by mass of the component (A).

### Surfactant or Leveling Agent

The resin composition may include a surfactant or a leveling agent. By compounding the surfactant or the leveling agent with the resin composition, it is possible to further improve applicability. Specifically, for example, by containing the surfactant or the leveling agent, it is possible to further prevent striation (the unevenness of the film thickness), or further improve developability.

Examples of the surfactant or the leveling agent include polyoxyethylene lauryl ether, polyoxyethylene stearyl ether, polyoxyethylene oleyl ether, and polyoxyethylene octyl phenol ether. Examples of commercially available products of the surfactant or the leveling agent include MEGAFACE F171, F173, and R-08 (manufactured by DIC Corporation, Product Name), Fluorad FC430 and FC431 (manufactured by Sumitomo 3M Limited, Product Name), and Organosiloxane Polymer KP341, KBM303, KBM403, and KBM803 (manufactured by Shin-Etsu Chemical Co., Ltd., Product Name).

The compounded amount in the case of using the surfactant or the leveling agent may be 0.001 to 5 parts by mass or 0.01 to 3 parts by mass with respect to 100 parts by mass of the component (A).

### Solvent

By the resin composition containing a solvent for dissolving and dispersing each component, it is easy to apply the resin composition onto the substrate, and it is possible to form the coated film with an even thickness.

Examples of the solvent include y-butyrolactone, ethyl lactate, propylene glycol monomethyl ether acetate, benzyl acetate, n-butyl acetate, ethoxyethyl propionate, 3-methyl methoxypropionate, N-methyl-2-pyrrolidone, N,N-dimethyl formamide, N,N-dimethyl acetamide, dimethyl sulfoxide, hexamethyl phosphoryl amide, tetramethylene sulfone, diethyl ketone, diisobutyl ketone, methyl amyl ketone, cyclohexanone, propylene glycol monomethyl ether, propylene glycol monopropyl ether, propylene glycol monobutyl ether, and dipropylene glycol monomethyl ether. Only one type of solvent can be used alone, or two or more types thereof can be used in combination.

The compounded amount of the solvent is not particularly limited, and it is preferable that the compounded amount is adjusted such that the ratio of the solvent in the resin composition is 20 to 90% by mass.

A semiconductor device according to this embodiment includes the cured resin film described above as a base of wiring with a wiring width of 3 μm or less and an inter-wiring distance of 3 μm or less. By using the cured resin film according to this embodiment as an interlayer insulating layer, it is possible to obtain an electronic component such as a semiconductor device excellent in the reliability with a high yield.

### EXAMPLES

Hereinafter, the present disclosure will be described in more detail, on the basis of Examples. However, the present invention is not limited to Examples described below.

Materials to prepare resin compositions of Examples and Comparative Examples will be described below. As the component (A), P-1 to P-6 were prepared. Mw and Tg of P-1 to P-6 are collectively shown in Table 1.

(P-1) Cresol Novolak Resin (m-Cresol/p-Cresol (molar ratio)=60/40, Mw=12000, Tg=165° C. (manufactured by ASAHI YUKIZAI CORPORATION, Product Name: EP4020G)

### P-2

100 parts by mass of a mixture of 4-tert-butoxystyrene and styrene (a molar ratio of 70:30), and 150 parts by mass of propylene glycol monomethyl ether were put in a flask, and retained at 70°° C. in a nitrogen atmosphere, 4 parts by mass of azobisisobutyronitrile (AIBN) was added thereto, and stirred for 10 hours at the number of rotations of approximately 150 rpm to cause a reaction. Next, a sulfuric acid was added to the reaction liquid to cause a reaction at 90° C. for 10 hours, and a tert-butoxy group is deprotected and converted into a hydroxy group. Ethyl acetate was added to the reaction liquid, water washing was repeated five times, and then, the organic phase was separated, and the solvent was removed to obtain P-2 that is a copolymer of p-hydroxystyrene/styrene.

(P-3) Cresol Novolak Resin (m-Cresol/p-Cresol (molar ratio)=60/40, Mw=4500, Tg=150° C. (manufactured by ASAHI YUKIZAI CORPORATION, Product Name: EP4080G)

### P-4

35.6 g of 4-hydroxyphenyl methacrylate, 78.0 g of 2-hydroxyethyl methacrylate, 20.0 g of N-acryloyloxyethyl hexahydrophthalimide (manufactured by TOAGOSEI CO., LTD., Product Name: M-140), 300 g of N,N-dimethyl acetamide (DMAc), and 6.43 g of azoisobutyronitrile (AIBN) were put in a flask to cause a reaction at 80° C. for 6 hours in a nitrogen atmosphere. 200 g of methanol was added thereto, and then, the liquid was slowly dropped into 1000 g of ion exchange water, and the precipitated polymer was filtered and dried to obtain P-4 that is an acrylic polymer having a phenolic hydroxyl group.

### P-5

7.07 g of 3,3′,4,4′-diphenyl ether tetracarboxylic dianhydride (ODPA), 0.831 g of 2-hydroxyethyl methacrylate (HEMA), and a catalytic amount of 1,4-diazabicyclo [2.2.2] octane were dissolved in 30 g of N-methyl-2-pyrrolidone (NMP), stirred at 45° C. for 1 hour, and then, cooled to 25° C. A solution in which 4.12 g of 2,2′-dimethyl biphenyl-4,4′-diamine (DMAP) was dissolved in NMP was added thereto, and then, stirred at 30° C. for 4 hours. After that, stirring was performed at a room temperature overnight to obtain a polyamide acid solution. 9.45 g of a trifluoroacetic anhydride was added to the polyamide acid solution, and stirred at 45° C. for 3 hours, and 7.08 g of HEMA and 0.01 g of benzoquinone were added thereto, and stirred at 45° C. for 20 hours. Such a reaction liquid was dropped into distilled water, and a precipitate was filtered and collected, and dried under a reduced pressure to obtain P-5 that is polyamide acid ester (a polyimide precursor).

### P-6

14.64 g (0.04 mol) of 2,2-bis(3-amino-4-hydroxyphenyl) hexafluoropropane (manufactured by Central Glass Co., Ltd., Product Name: BIS-AP-AF), which is an amine component, 19.48 g (0.045 mol) of polyoxypropylene diamine (manufactured by BASF, Product Name: D-400), 2.485 g (0.01 mol) of 3,3′-(1,1,3,3-tetramethyl disiloxane-1,3-diyl) bispropyl amine (manufactured by Dow Corning Toray Co., Ltd., Product Name: BY16-871EG), and 80 g of NMP were prepared in 300 mL of a flask provided with a stirrer, a thermometer, a nitrogen substitution unit (a nitrogen inflow pipe), and a reflux condenser with a moisture acceptor, and stirred to dissolve the amine component in NMP. 31 g (0.1 mol) of ODPA was gradually added to the solution in the flask while cooling the flask in an ice bath. After the adding was ended, the solution was heated to 180° C. and the temperature was retained for 5 hours while blowing nitrogen gas to obtain an NMP solution of P-6 that is polyimide having a hydroxyl group.

Tg of the component (A) is the peak temperature of tan δ when the component (A) formed into a film is measured by a viscoelasticity analyzer (manufactured by Rheometric Scientific, Inc., Product Name: RSA-2) in the condition of a temperature increase rate of 5° C./minute, a frequency of 1 Hz, and a measurement temperature of −50 to 300° C. Mw is a value measured in terms of polystyrene by using high-performance liquid chromatography (manufactured by SHIMADZU CORPORATION, Product Name: C-R4A).

TABLE 1

| Component (A) | | Mw | Tg (° C.) |
|---|---|---|---|
| P-1 | Cresol novolak resin | 12000 | 165 |
| P-2 | Copolymer of p- | 10000 | 130 |
| | hydroxystyrene/styrene | | |
| P-3 | Cresol novolak resin | 4500 | 150 |
| P-4 | Acrylic polymer having phenolic | 22000 | 100 |
| | hydroxyl group | | |
| P-5 | Polyimide precursor | 25500 | 150 |
| P-6 | Polyimide having hydroxyl group | 42000 | 65 |

As the component (B), thermosetting compounds (B-1) and (B-2), and photopolymerizable compounds (B-3) and (B-4) were prepared.
(B-1) 4,4′,4″-Ethylidene Tris[2,6-(Methoxymethyl) Phenol] (manufactured by Honshu Chemical Industry Co., Ltd., Product Name: HMOM-TPHAP)
(B-2) Bisphenol A Bis(Triethylene Glycol Glycidyl Ether) Ether (manufactured by New Japan Chemical Co., Ltd., Product Name: BEO-60E)
(B-3) Tetraethylene Glycol Dimethacrylate (manufactured by SHIN-NAKAMURA CHEMICAL Co., Ltd., Product Name: TEGDMA)
(B-4) Ethoxypentaerythritol Tetraacrylate (manufactured by SHIN-NAKAMURA CHEMICAL Co., Ltd., Product Name: ATM-4E)

As the component (C), the following photosensitizing agents were prepared.
(C-1) 1-Naphthoquinone-2-Diazide-5-Sulfonic Acid Ester of Tris(4-Hydroxyphenyl) Methane (an esterification rate of approximately 95%)
(C-2) Ethanone, 1-[9-Ethyl-6-(2-Methyl Benzoyl)-9H-Carbazol-3-Y1]-, 1-(O-Acetyl Oxime) (manufactured by BASF Japan Ltd., Product Name: IRGACURE OXE02)
(C-3) 1-Phenyl-1,2-Propanedione-2-(O-Ethoxycarbonyl) Oxime (manufactured by Lambson, Product Name: G-1820 (PDO))

### Preparation of Resin Composition

### Examples 1 to 5

The components (A) to (C) in compounded amounts (parts by mass) shown in Table 2, 120 parts by mass of ethyl lactate as a solvent, and 2 parts by mass of an ethanol solution of 50% by mass of 3-glycidoxypropyl triethoxysilane (manufactured by Shin-Etsu Chemical Co., Ltd., Product Name: KBE-403) as a coupling agent were mixed. The mixture was filtered under a pressure by using a polytetrafluoroethylene resin filter with 3 μm holes to obtain a resin composition.

### Example 6

The components (A) to (C) in compounded amounts (parts by mass) shown in Table 2, 150 parts by mass of NMP as a solvent, and 2 parts by mass of an ethanol solution of 50% by mass of KBE-403 were mixed. The mixture was filtered under a pressure by using a polytetrafluoroethylene resin filter with 3 μm holes to obtain a resin composition. (Comparative Examples 1, 2, and 4)

The components (A) to (C) in compounded amounts (parts by mass) shown in Table 3, 120 parts by mass of ethyl lactate as a solvent, and 2 parts by mass of an ethanol solution of 50% by mass of KBE-403 were mixed. The mixture was filtered under a pressure by using a polytetrafluoroethylene resin filter with 3 μm holes to prepare a resin composition.

### Comparative Example 3

The components (A) to (C) in compounded amounts (parts by mass) shown in Table 3, 150 parts by mass of NMP as a solvent, and 2 parts by mass of an ethanol solution of 50% by mass of KBE-403 were mixed. The mixture was filtered under a pressure by using a polytetrafluoroethylene resin filter with 3 μm holes to prepare a resin composition.

### Evaluation

### Preparation of Cured Resin Film

The resin composition was applied onto a 6-inch silicon wafer by a spin coater such that the film thickness after curing was 12 μm, and heated on a hot plate at 120° C. for 3 minutes to form a resin film. The silicon wafer on which the resin film was formed was heated at a temperature shown in Table 2 or 3 for 2 hours in a nitrogen atmosphere to form a cured resin film on the silicon wafer.

### Storage Elastic Modulus

The cured resin film was cut out into the shape of a strip having a width of 10 mm and a length of 100 mm to prepare a strip sample. By using a dynamic viscoelasticity measurement device (manufactured by UBM, Product Name: Rheogel-E4000), a viscoelastic test of the strip sample was performed at an interchuck distance of 20 mm, a frequency of 10 Hz, and a temperature increase rate of 5° C./minute, in a temperature range of 40 to 350° C., to measure a storage elastic modulus at 140° C.

### Cross-Linking Density

The cross-linking density of the cured resin film was calculated from the storage elastic modulus at 300° C. (573K) measured in the viscoelastic test described above.

### Glass Transition Temperature

A temperature indicating the maximum value of tan δ measured in the viscoelastic test described above was set as the glass transition temperature (Tg) of the cured resin film.

### Sample for Evaluating Resistance Value

A metal seed layer composed of a titanium seed layer having a thickness of 25 nm and a copper seed layer having a thickness of 150 nm was formed by sputtering on the cured resin film. A resist layer having a thickness of 5 μm was formed on the metal seed layer by using a photoresist for plating (manufactured by TOKYO OHKA KOGYO CO., LTD., Product Name: PMER P-LA900PM), and then, the resist layer was exposed and developed to form a resist pattern having Resist Width/Space Width of 2 μm/2 μm on the metal seed layer. Next, by electrolytic copper plating, a copper wiring pattern having a thickness of 3 μm was formed on the metal seed layer where the resist pattern was not formed. After that, the resist pattern was removed by being immersed in NMP for 5 minutes, the copper seed layer was removed by being immersed in a copper etchant (manufactured by MITSUBISHI GAS CHEMICAL COMPANY, INC., Product Name: WLC-C2) for 40 seconds, and the titanium seed layer was removed by being immersed in a titanium etchant (a mixed liquid of WLC-T and an aqueous solution of 28% by mass of ammonia) for 7 minutes. According to such an operation, an evaluation sample including comb-type copper wiring with a wiring height of 4 μm, a wiring width of 2 μm, and an inter-wiring distance of 2 μm and comb-type copper wiring with a wiring height of 4 μm, a wiring width of 5 μm, and an inter-wiring distance of 5 μm was obtained. In addition, according to the same operation except that a resist pattern having Resist Width/Space Width of 5 μm/5 m was formed, an evaluation sample including comb-type copper wiring with a wiring width of 5 μm and an inter-wiring distance of 5 μm was obtained.

### Resistance Value

The interelectrode resistance value of the evaluation sample was measured by using an ohmmeter (manufactured by HIOKI E.E. CORPORATION, Product Name: RM3544). A case where the resistance value was 10⁹ Ω or more was evaluated as “A”, a case where the resistance value was 10⁷ Ω or more and less than 10⁹ Ω was evaluated as “B”, and a case where the resistance value was less than 10⁷ Ω was evaluated as “C”. In the evaluation sample prepared in Comparative Example 4, since the wiring was peeled off during etching, the resistance value was not measurable.

### Fine Wiring Yield

The interelectrode resistance value of the evaluation sample at a wiring width of 2 μm and an inter-wiring distance of 2 μm was measured at 10 spots, the ratio of evaluation “A” and “B” of the resistance value was set as a yield, a case where the yield was 75 to 100% was evaluated as “A”, a case where the yield was 50% or more and less than 75% was evaluated as “B”, and a case where the yield was less than 50% was evaluated as “C”.

TABLE 2

| Example | | 1 | 2 | 3 | 4 | 5 | 6 |
|---|---|---|---|---|---|---|---|
| (A) | P-1 | 60 | 75 | 75 | 75 | — | — |
| | P-2 | — | — | — | — | 100 | — |
| | P-3 | 40 | 25 | 25 | — | — | — |
| | P-4 | — | — | — | 25 | — | — |
| | P-5 | — | — | — | — | — | 100 |
| | P-6 | — | — | — | — | — | — |
| (B) | B-1 | 15 | 15 | 15 | 15 | 15 | — |
| | B-2 | 10 | 10 | 10 | 10 | 10 | — |
| | B-3 | — | — | — | — | — | 6 |
| | B-4 | — | — | — | — | — | 4 |
| (C) | C-1 | 15 | 15 | — | 15 | 15 | — |
| | C-2 | — | — | — | — | — | 0.3 |
| | C-3 | — | — | — | — | — | 4 |
| KBE-403 | | 1 | 1 | 1 | 1 | 1 | 1 |
| Curing temperature (° C.) | | 220 | 220 | 220 | 220 | 220 | 200 |
| Cross-linking | | 53 | 98 | 94 | 13 | 13 | 0.6 |
| density (×10⁻³ mol/cm³) | | | | | | | |
| Storage elastic | | 3.0 | 3.5 | 2.8 | 2.5 | 2.9 | 1.2 |
| modulus (GPa) at 140° C. | | | | | | | |
| Tg (° C.) | | 241 | 227 | 212 | 253 | 262 | 227 |
| Resistance | 2 μm/2 μm | A | A | A | A | A | B |
| value | 5 μm/5 μm | A | A | A | A | A | A |

| | | | | | | |
|---|---|---|---|---|---|---|
| Fine wiring yield | A | B | B | A | A | B |

TABLE 3

| Comparative Example | | 1 | 2 | 3 | 4 |
|---|---|---|---|---|---|
| (A) | P-1 | 40 | 60 | — | 80 |
| | P-2 | — | — | — | — |
| | P-3 | — | 40 | — | 20 |
| | P-4 | — | — | — | |
| | P-5 | — | — | 100 | — |
| | P-6 | 60 | — | — | — |
| (B) | B-1 | 5 | 1 | — | 40 |
| | B-2 | 5 | 1 | — | 10 |
| | B-3 | — | — | 6 | — |
| | B-4 | — | — | 4 | — |
| (C) | C-1 | 15 | 15 | — | 15 |
| | C-2 | — | — | 0.3 | — |
| | C-3 | — | — | 4 | — |
| KBE-403 | | 1 | 1 | 1 | 1 |
| Curing temperature (° C.) | | 230 | 220 | 160 | 350 |
| Cross-linking | | 0.08 | 0.05 | 0.08 | 120 |
| density (×10⁻³ mol/cm³) | | | | | |
| Storage elastic | | 0.9 | 0.7 | 0.7 | 4.3 |
| modulus (GPa) at 140° C. | | | | | |
| Tg(° C.) | | 191 | 186 | 194 | 270 |
| Resistance | 2 μm/2 μm | C | C | C | — |
| value | 5 μm/5 μm | A | A | B | — |

| | | | | |
|---|---|---|---|---|
| Fine wiring yield | C | C | C | — |

### REFERENCE SIGNS LIST

1: cured resin film, 2: metal seed layer, 3: wiring portion, 4: metal wiring, S: substrate, R: resist pattern.

1. A method for producing a semiconductor device, comprising:
a step of applying a resin composition onto a substrate and drying the resin composition to form a resin film;
a step of heating the resin film to obtain a cured resin film;
a step of forming a metal seed layer by sputtering on a surface of the cured resin film;
a step of forming a resist pattern having an opening portion for forming a wiring pattern on a surface of the metal seed layer;
a step of forming a metal layer having a wiring pattern with a wiring width of 3 μm or less and an inter-wiring distance of 3 μm or less by electrolytic plating in a region on the surface of the metal seed layer, which is exposed from the resist pattern;
a step of removing the resist pattern; and
a step of removing the metal seed layer exposed by the removal of the resist pattern, in this order,
wherein a cross-linking density of the cured resin film is 0.1×10⁻³ to 110×10⁻³ mol/cm³.

2. The method for producing a semiconductor device according to claim 1, wherein a storage elastic modulus at 140° C. of the cured resin film is 1.0 GPa or more.

3. The method for producing a semiconductor device according to claim 1, wherein a glass transition temperature of the cured resin film is 200° C. or higher.

4. The method for producing a semiconductor device according to claim 1, wherein the cross-linking density of the cured resin film is 60×10⁻³ mol/cm³ or less.

5. The method for producing a semiconductor device according to claim 1, wherein the resin composition includes a base polymer (A) and a cross-linking component (B), and the base polymer (A) contains a polymer having a phenolic hydroxyl group, a carboxy group, an imide group, a benzoxazole group, or a photopolymerizable ethylenically unsaturated group.

6. A cured resin film used as a base of a wiring pattern with a wiring width of 3 μm or less and an inter-wiring distance of 3 μm or less, wherein a cross-linking density is 0.1×10⁻³ to 110×10⁻³ mol/cm³.

7. The cured resin film according to claim 6, wherein a storage elastic modulus at 140° C. is 1.0 GPa or more.

8. The cured resin film according to claim 6, wherein a glass transition temperature is 200° C. or higher.

9. The cured resin film according to claim 6, wherein the cross-linking density of the cured resin film is 60×10⁻³ mol/cm³ or less.

10. The cured resin film according to claim 6, wherein the cured resin film includes a cured material of a resin composition including a base polymer (A) and a cross-linking component (B), and the base polymer (A) contains a polymer having a phenolic hydroxyl group, a carboxy group, an imide group, a benzoxazole group, or a photopolymerizable ethylenically unsaturated group.

11. A semiconductor device, comprising the cured resin film according to claim 6 as a base of wiring with a wiring width of 3 μm or less and an inter-wiring distance of 3 μm or less.
